(19) United States
(12) Patent Application Publication
(10) Pub. No.: US 2018/0355184 A1
(43) Pub. Date: Dec. 13, 2018

(54) CURABLE RESIN COMPOSITION, CURABLE RESIN MOLDED ARTICLE, CURED PRODUCT, LAMINATE, COMPLEX, AND MULTI-LAYER PRINTED CIRCUIT BOARD

(71) Applicant: ZEON CORPORATION, Tokyo (JP)

(72) Inventors: Makoto FUJIMURA, Tokyo (JP); Takashi IGA, Tokyo (JP)

(21) Appl. No.: 15/512,034

(22) PCT Filed: Oct. 22, 2015
(86) PCT No.: PCT/IB2015/002264

§ 371 Date: Oct. 20, 2017

(30) Foreign Application Priority Data
Sep. 17, 2014 (JP) JP2014-189183

(51) Int. Cl. C09D 4/00; C09D 163/00; H05K 1/03; H05K 1/02; B32B 27/38; B32B 27/08

(52) U.S. Cl. CPC C09D 4/00; C09D 163/00; H05K 1/0373; C08K 9/06; B32B 27/38; B32B 27/08; H05K 1/0271

(57) ABSTRACT

[Problem] To provide a curable resin composition which has a low linear expansion coefficient and high heat resistance, which can form a cured product in which the occurrence of void defects and the like is suppressed, and with which the toughness or a molded article can be maintained. [Solution] A curable resin composition comprising an epoxy compound (A), an epoxy curing agent (B), an inorganic filter (C), and a compound (D) including at least three ethylenically unsaturated bonds, wherein the ratio of the inorganic filler (C) in a non-volatile component exceeds 50 mass %.

### TECHNICAL FIELD

The present invention relates to a curable resin composition, curable resin molded article, cured product, laminate body, composite, and multilayer printed circuit board.

### BACKGROUND ART

In recent years, higher density in circuit boards used in semiconductor elements and the like in electronic equipment is required in conjunction with the pursuit of miniaturization, multifunctionalization, high speed communication, and the like of electronic equipment, and in response to this requirement, circuit boards having a multilayer structure (hereinafter, referred to as “multilayer circuit boards”) are used. Furthermore, the multilayer circuit board is formed, for example, by laminating an electrical insulating layer on an inner layer substrate including a core substrate obtained by forming an electrical insulating layer on both surfaces of the substrate, and a conductor layer (wiring layer) formed on a surface of the core substrate to form the conductor layer on the electrical insulating layer, and then repeatedly performing: lamination of the electrical insulating layer with regard to the substrate obtained by sequentially forming the electrical insulating layer and conductor layer on the inner layer substrate, and formation of the conductor layer.

Herein, a small coefficient of linear expansion, favorable electrical properties, and the like are required in the electrical insulating layer of the multilayer circuit board. This is because if the coefficient of linear expansion of the electrical insulating layer is large, deformation of the multilayer circuit board increases. This requirement is also because if the electrical properties are insufficient and a dielectric tangent of the electrical insulating layer is large, deterioration of an electrical signal increases, and improving the performance of the multilayer circuit board cannot be sufficiently accommodated.

Therefore, a curable resin composition containing a radical polymerizable compound having at least one type selected from styryl groups, allyl groups, vinyl groups, acryl groups, methacryl groups, and propenyl groups, an epoxy resin, a curing agent, a roughening component, and an inorganic filler material has been proposed as a conventional resin composition that can form an electrical insulating layer with a low coefficient of linear expansion and dielectric tangent (for example, refer to Patent Document 1). Furthermore, based on the curable resin composition according to Patent Document 1, the dielectric tangent of an electrical insulating layer obtained by molding and curing the resin composition can be reduced using a radical polymerizable compound. Furthermore, a thermosetting resin composition according to Patent Document 1 contains an inorganic filler material, and therefore, an electrical insulating layer with a low coefficient of linear expansion can be formed when the resin composition is molded and cured.

### PRIOR ART DOCUMENTS

### Patent Document

Patent Document 1: Japanese Unexamined Patent Application Publication No. 2014-34580

### SUMMARY OF THE INVENTION

### Problem to be Solved by the Invention

However, although there is demand for further improving the reliability of the electrical insulating layer in accordance with increased demand for finer wiring and thinner multilayer circuit boards in recent years, there is room for improvement for the thermosetting resin composition according to Patent Document 1 from the perspective of not only reducing the coefficient of linear expansion of the cured product obtained using the electrical insulating layer, but also of suppressing void defects and the like from occurring in a cured product as well as further improving the heat resistance of the cured product. Furthermore, if the coefficient of linear expansion of a cured product is reduced by adding an inorganic filler material or the like, a molded article obtained by molding the thermosetting resin composition is prone to be brittle, but toughness of the molded article must be ensured in the conventional thermosetting resin composition.

An object of the present invention is to provide a curable resin composition having a low linear expansion coefficient and high heat resistance, which can form a cured product where the occurrence of void defects and the like is suppressed, and which can ensure toughness of a molded article.

Furthermore, an object of the present invention is to provide a curable resin molded article having favorable toughness and having a low coefficient of linear expansion and high heat resistance, and which can form a cured product where the occurrence of void defects and the like is suppressed.

Furthermore, an object of the present invention is to provide a cured product having a low coefficient of linear expansion and high heat resistance, where the occurrence of void defects and the like is suppressed, as well as a laminate body, composite, and multilayer printed circuit board formed using the cured product.

### Means for Solving the Problems

The present inventors performed extensive studies to achieve the aforementioned objects. Furthermore, the present inventors discovered that for a curable resin composition containing an epoxy compound, epoxy curing agent, and inorganic filler material, by further adding a compound containing three or more ethylenically unsaturated bonds in conjunction with setting the added amount of the inorganic filler material to a predetermined amount, a cured product having a low coefficient of linear expansion and high heat resistance, where the occurrence of a void defect and the like is suppressed can be formed, thus completing the present invention.

In other words, the invention aims at advantageously resolving the aforementioned problems, and a curable resin composition of the present invention contains: an epoxy compound (A); an epoxy curing agent (B); an inorganic filler material (C); and a compound (D) containing three or more ethylenically unsaturated bonds; where the ratio of the inorganic filler material (C) in a nonvolatile component exceeds 50 mass %. Thereby, if the ratio of the inorganic filler material (C) in the nonvolatile component exceeds 50 mass %, a cured product having a low coefficient of linear expansion can be formed. Furthermore, if the compound (D) containing three or more ethylenically unsaturated bonds is added, a cured product having high heat resistance, where the occurrence of void defects and the like is suppressed can be formed, and toughness of the curable resin molded article formed using the curable resin composition can be ensured.

Note that in the present invention, “nonvolatile component” of the curable resin composition refers to a component that remains without volatilizing when the curable resin composition is vacuum dried for 3 hours at a temperature of 120° C.

Herein, in the curable resin composition of the present invention, the compound (D) containing three or more ethylenically unsaturated bonds is preferably a chain compound. This is because if the compound (D) containing three or more ethylenically unsaturated bonds is a chain compound that does not have a cyclic structure in a molecule, toughness of a curable resin molded article formed using the curable resin composition can be enhanced, and a cured product with excellent heat resistance can be obtained.

Furthermore, in the curable resin composition, the compound (D) containing three or more ethylenically unsaturated bonds preferably includes a compound that is liquid at ambient temperature and ambient pressure. This is because if a compound that is liquid at ambient temperature and ambient pressure is used as the compound (D) containing three or more ethylenically unsaturated bonds, the toughness of a curable resin molded article formed using the curable resin composition can be enhanced.

Note that in the present invention, “liquid at ambient temperature and ambient pressure” refers to being liquid under a condition where the temperature is 20° C. and atmospheric pressure is I atm.

Furthermore, in the curable resin composition of the present invention, the compound (D) containing three or more ethylenically unsaturated bonds preferably includes at least one type of compound selected from a group containing (meth)acrylate compounds expressed by the following general formulas:

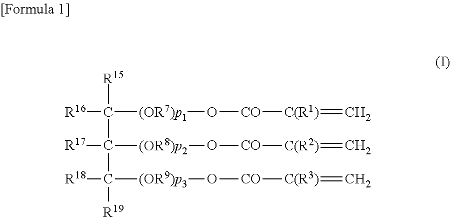

[where R¹ to R³ individually represent a hydrogen atom or a methyl group; R⁷ to R⁹ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ individually represent an integer from 0 to 10; and R¹⁵ to R¹⁹ individually represent a hydrogen atom or an alkyl group with 1 to 10 carbon atoms.];

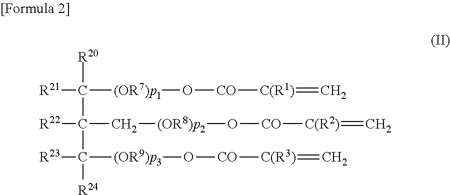

[where R¹ to R³ individually represent a hydrogen atom or a methyl group; R⁷ to R⁹ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ individually represent an integer from 0 to 10; and R²⁰ to R²⁴ individually represent a hydrogen atom or an alkyl group with 1 to 10 carbon atoms.];

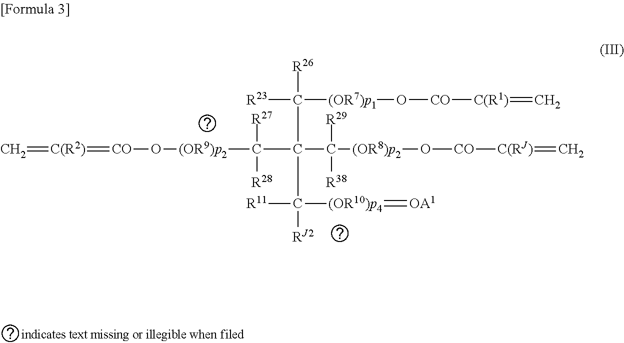

[where R¹ to R³ individually represent a hydrogen atom or a methyl group; R⁷ to R¹⁰ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ individually represent an integer from 0 to 10; R²⁵ to R³² individually represent a hydrogen atom or an alkyl group with 1 to 10 carbon atoms; and A¹ represents a hydrogen atom, an alkyl group, or —CO—C(R⁴)═CH₂ (where R⁴ represents a hydrogen atom or a methyl group).]; and

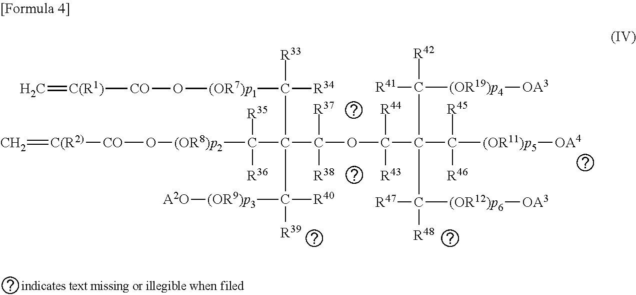

[where R¹ to R³ individually represent a hydrogen atom or a methyl group; R⁷ to R¹² individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₆ individually represent an integer from 0 to 10; R³³ to R⁴⁸ individually represent a hydrogen atom or an alkyl group with 1 to 10 carbon atoms; one of A and A³ represents CO—C(R³)═CH₂ (where R³ represents a hydrogen atom or methyl group), and the other represents a hydrogen atom, an alkyl group, or —CO—C(R⁴)═CH₂ (where R⁴ represents a hydrogen atom or a methyl group); A⁴ represents a hydrogen atom, an alkyl group, or —CO—C(R⁵)═CH₂ (where R⁵ represents a hydrogen atom or a methyl group); and A⁵ represents a hydrogen atom, an alkyl group, or —CO—C(R⁶)—CH₂ (where R⁶ represents a hydrogen atom or a methyl group).].

This is because if the aforementioned (meth)acrylate compound is used as the compound (D) containing three or more ethylenically unsaturated bonds, a cured product having high heat resistance, where the occurrence of void defects and the like is suppressed can be easily formed.

Note that in the present invention, “(meth)acrylate” refers to an acrylate and/or a methacrylate.

Furthermore, in the curable resin composition of the present invention, the ratio of the compound (D) containing three or more ethylenically unsaturated bonds in a nonvolatile component is preferably 0.1 mass % to 15 mass %. This is because if the ratio of the compound (D) containing three or more ethylenically unsaturated bonds is at or above the aforementioned lower limit, an effect of adding the compound (D) containing three or more ethylenically unsaturated bonds can be sufficiently achieved. Furthermore, this is because if the ratio of the compound (D) containing three or more ethylenically unsaturated bonds is at or below the aforementioned upper limit, the dielectric tangent of a cured product can be suppressed from increasing.

Furthermore, in the curable resin composition of the present invention, the compound (D) containing three or more ethylenically unsaturated bonds is preferably included at a ratio of 0.2 parts by mass to 30 parts by mass per 100 parts by mass of the inorganic filler material (C). This is because if the ratio of the compound (D) containing three or more ethylenically unsaturated bonds is at or above the aforementioned lower limit, an effect of adding the compound (D) containing three or more ethylenically unsaturated bonds can be sufficiently achieved. Furthermore, this is because if the ratio of the compound (D) containing three or more ethylenically unsaturated bonds is at or below the aforementioned upper limit, the dielectric tangent of a cured product can be suppressed from increasing.

Furthermore, in the curable resin composition of the present invention, the epoxy curing agent (B) preferably contains an active ester curing agent. This is because if an active ester curing agent is used as the epoxy curing agent (B), a cured product can be easily formed.

Furthermore, the invention aims at advantageously resolving the aforementioned problems, and a curable resin molded article of the present invention is formed using the aforementioned curable resin composition. Based on the curable resin molded article formed using the aforementioned curable resin composition, a cured product having a low coefficient of linear expansion and high heat resistance, where the occurrence of void defects and the like is suppressed can be formed. Furthermore, if the aforementioned curable resin composition is used, a curable resin molded article with favorable toughness is obtained.

Furthermore, the invention aims at advantageously resolving the aforementioned problems, and a cured product of the present invention is obtained by curing the aforementioned curable resin molded article. The cured product obtained by curing the aforementioned curable resin molded article has a low coefficient of linear expansion and high heat resistance, and occurrences of void defect and the like are suppressed.

Furthermore, if the aforementioned cured product is used, a laminate body formed by laminating the cured product and a substrate, a composite obtained by forming a conductor layer on a surface of a cured product side of the laminate body, and a multilayer printed circuit board formed using the composite can be appropriately formed. Note that the obtained laminate body, composite, and multilayer printed circuit board have excellent connection reliability between the cured product and substrate, cured product and conductor layer, or the like in a temperature changing environment or high temperature environment.

### Effect of the Invention

The present invention can provide a curable resin composition having a low linear expansion coefficient and high heat resistance, which can form a cured product where the occurrence of void defects and the like is suppressed, and can ensure toughness of a molded article.

Furthermore, the present invention can provide a curable resin molded article having favorable toughness and having a low coefficient of linear expansion and high heat resistance, which can form a cured product where the occurrence of void defects and the like is suppressed.

Furthermore, the present invention can provide a cured product having a low coefficient of linear expansion and high heat resistance, where the occurrence of void defects and the like is suppressed, as well as a laminate body, composite, and multilayer printed circuit board formed using the cured product.

### DESCRIPTION OF EMBODIMENTS

An embodiment of the present invention is described below in detail.

Herein, a curable resin composition of the present invention is a resin composition that can be cured by heating or the like, which can be used in manufacturing a curable resin molded article of the present invention. Furthermore, the curable resin molded article of the present invention formed using the curable resin composition of the present invention can be used in manufacturing a cured product of the present invention which can be suitably used as an electrical insulating layer or the like. Furthermore, the cured product of the present invention can be suitably used in manufacturing a laminate body formed by laminating the cured product and a substrate, a composite obtained by forming a conductor layer on a surface on a cured product side of the conductor layer, and a multilayer printed circuit board formed using the composite.

### Curable Resin Composition

The curable resin composition of the present invention contains: an epoxy compound (A); an epoxy curing agent (B); an inorganic filler material (C); and a compound (D) containing three or more ethylenically unsaturated bonds; where the ratio of the inorganic filler material (C) in a nonvolatile component exceeds 50 mass %. Note that the curable resin composition of the present invention may contain, in addition to the aforementioned components, a solvent or other additive that is generally added to a resin composition used in forming an electrical insulating layer.

### Epoxy Compound (A)

The epoxy compound (A) is not particularly limited, and examples include compounds having two or more epoxy groups in one molecule, such as epoxy compounds having an alicyclic olefin structure, epoxy compounds having a fluorene structure, phenol novolac epoxy compounds, cresol novolac epoxy compounds, cresol epoxy compounds, bisphenol A epoxy compounds, bisphenol F epoxy compounds, bisphenol S epoxy compounds, bisphenol AF epoxy compounds, polyphenol epoxy compounds, brominated bisphenol A epoxy compounds, brominated bisphenol F epoxy compounds, hydrogenated bisphenol A epoxy compounds, alicyclic epoxy compounds, glycidyl ester epoxy compounds, glycidyl amine epoxy compounds, tert-butyl-catechol epoxy compounds, naphthol epoxy compounds, naphthalene epoxy compounds, naphthylene ether epoxy compounds, biphenyl epoxy compounds, anthracene epoxy compounds, linear aliphatic epoxy compounds, epoxy compounds having a butadiene structure, heterocyclic epoxy compounds, epoxy compounds containing a spiro ring, cyclohexane dimethanol epoxy compounds, trimethylol epoxy compounds, and the like.

One of these compounds can be used independently, or two or more can be combined.

Of these, the epoxy compound (A) is preferably an epoxy compound having two or more glycidyl groups, and more preferably a biphenol epoxy compound or epoxy compound having an alicyclic olefin structure, from the perspective of being able to obtain a curable resin composition, a curable resin molded article using the curable resin composition, a cured product obtained by curing the curable resin molded article, and the like with favorable mechanical properties and heat resistance. Furthermore, a mixture of the epoxy compound having an alicyclic olefin structure or biphenol epoxy compound and a polyfunctional epoxy compound having three or more epoxy groups in one molecule is particularly preferably used as the epoxy compound (A) from the perspective of being able to obtain a cured product with more favorable electrical properties and heat resistance.

Note that the epoxy compound having an alicyclic olefin structure is not particularly limited, and examples include epoxy compounds having a dicyclopentadiene skeleton. Furthermore, examples of the epoxy compounds having a dicyclopentadiene skeleton include: products of the trade names “Epiclon HP7200L”, “Epiclon HP7200”, “Epiclon HP7200H”, “Epiclon HP7200HH”, and “Epiclon HP7200HHH” (aforementioned products manufactured by DIC Corporation); a product of the trade names “Tactix 558” (manufactured by Huntsman Advanced Materials); and products of the trade names “XD-1000-IL” and “XD-1000-2L” (aforementioned products manufactured by Nippon Kayaku Co., Ltd.)

Furthermore, examples of the biphenol epoxy compounds include: products of the trade names “INC3000H”, “NC3000L”, “NC3000”, and “NC3100” (aforementioned products manufactured by Nippon Kayaku Co., Ltd.); and product of the trade names “YX4000”, “YX4000H”, “YX4000HK”, and “YL6121” (aforementioned products manufactured by Mitsubishi Chemical Corporation).

Furthermore, examples of the polyfunctional epoxy compounds include products of the trade names “1031 S”, “630”, “604”, and “1032 H60” (aforementioned products manufactured by Mitsubishi Chemical Corporation).

### Epoxy Curing Agent (B)

The epoxy curing agent (B) is not particularly limited, and examples include active ester curing agents, cyanate ester curing agents, phenol curing agents, benzoxazine curing agents, and the like. Of these, an active ester curing agent is preferably used from the perspective of enabling reduction of the dielectric tangent.

Note that one epoxy curing agent (B) can be used independently, or two or more can be combined.

Herein, a compound having an active ester group which is a group having reactivity with regard to an epoxy group in the epoxy compound (A) can be used as the active ester curing agent. Furthermore, a compound having at least two active ester groups per molecule is preferably used as the active ester curing agent. Note that the active ester group is an ester group that does not form a hydroxyl group (—OH) by reacting with an —O portion of a ring-opened epoxy group when reacting with an epoxy group. More specifically, an active ester group is an ester group that produces an electron-withdrawing group other than a proton (H+) when reacting with an epoxy group.

Specifically, from the perspective of heat resistance and the like, the active ester curing agent is preferably an active ester compound obtained by condensation reacting a carboxylic acid compound and/or thiocarboxylic acid compound with a hydroxy compound and/or thiol compound for example, more preferably an active ester compound obtained from reacting one or more types selected from a group consisting carboxylic acid compounds, phenol compounds, naphthol compounds, and thiol compounds, and particularly preferably an aromatic compound having at least two active ester groups per molecule, obtained by reacting a carboxylic acid compound with an aromatic compound having a phenolic hydroxyl group. Note that examples of the carboxylic acid compounds, thiocarboxylic acid compounds, phenol compounds, naphthol compounds, and thiol compounds that can be used in preparing the active ester curing agent include compounds described in Japanese Unexamined Patent Application Publication No. 2011-132507.

Furthermore, the active ester curing agent can be an active ester compound disclosed in Japanese Unexamined Patent Application Publication No. 2002-12650 and Japanese Unexamined Patent Application Publication No. 2004-277460 or a commercially available active ester curing agent, for example. Examples of commercially available active ester curing agents include products of the trade names “EXB9451”, “EXB9460”, “EXB9460S”, and “HPC8000-65T” (aforementioned products manufactured by DIC Corporation), and the like.

### Inorganic Filler Material (C)

An inorganic filler material that is generally industrially used can be used as the inorganic filler material (C). Specifically, an inorganic filler material described in Japanese Unexamined Patent Application Publication No. 2012-136646 can be used as the inorganic filler material (C). Of these, silica is particularly preferable, because fine particles are easy to obtain. Note that the inorganic filler material may be treated with a silane coupling agent or treated with stearic acid or other organic acid, and is preferably treated with a silane coupling agent from the perspective of dispersibility, water resistance, and the like.

Herein, in the curable resin composition of the present invention, the inorganic filler material (C) can be added to reduce the coefficient of linear expansion of a cured product. Furthermore, the ratio occupied by the inorganic filler material (C) in a nonvolatile component of the curable resin composition must exceed 50 mass % from the perspective of sufficiently reducing the coefficient of linear expansion when the curable resin composition of the present invention is used as a cured product. This is because if the ratio of the inorganic filler material (C) in a nonvolatile component is 50 mass % or less, the expansion rate of the cured product cannot be sufficiently reduced. For example, if an electrical insulating layer of a multilayer circuit board is formed using the curable resin composition, the coefficient of linear expansion of the electrical insulating layer may increase, and the multilayer printed circuit board may greatly deform.

Note that from the perspective of sufficiently reducing the coefficient of linear expansion of the cured product, the ratio of the inorganic filler material (C) in a nonvolatile component is preferably 55 mass % or more, and more preferably 60 mass % or more. Furthermore, the ratio of the inorganic filler material (C) in a nonvolatile component is normally 85 mass % or less, and preferably 80 mass % or less.

Incidentally, while a solvent used in preparing the curable resin composition is generally mostly volatilized when vacuum drying for 3 hours at a temperature of 120° C., the epoxy compound (A), the epoxy curing agent (B), the inorganic filler material (C), the compound (D) having three or more ethylenically unsaturated bonds, and other additives do not mostly volatilize even if vacuum dried for 3 hours at a temperature of 120° C. Therefore, the ratio of the inorganic filler material (C) in a nonvolatile component of the curable resin composition is normally approximately equal to the ratio of the added amount of the inorganic filler material (C) with regard to the total amount of the epoxy compound (A), epoxy curing agent (B), inorganic filler material (C), compound (D) containing three or more ethylenically unsaturated bonds, and other additives, used in preparing the curable resin composition.

### Compound (D) Containing Three or More Ethylenically Unsaturated Bonds

The compound (D) containing three or more ethylenically unsaturated bonds is not particularly limited, and can be a compound having three or more ethylenically unsaturated bonds in one molecule. Furthermore, in the curable resin composition of the present invention, the compound (D) containing three or more ethylenically unsaturated bonds is added, and therefore, the heat resistance of a cured product can be improved, and void defects and the like can be suppressed from occurring in the cured product. Furthermore, the toughness of a curable resin molded article can be ensured. Note that if only a compound where the number of ethylenically unsaturated bonds included per molecule is two or lower is used, the heat resistance of the cured product cannot be sufficiently improved. Furthermore, from the perspective of improving the heat resistance of the cured product, the number (functional number) of ethylenically unsaturated bonds included in the compound (D) containing three or more ethylenically unsaturated bonds is preferably 4 or higher, and more preferably 5 or higher.

Herein, the compound (D) containing three or more ethylenically unsaturated bonds is not particularly limited, and examples include a (meth)acrylate compound containing three or more (meth)acryloyloxy groups per molecule, and allyl group-containing compounds containing three or more allyl groups per molecule.

Note that in the present invention, “(meth)acryloyl” refers to acryloyl and/or methacryloyl. Furthermore, one of the compounds (D) containing three or more ethylenically unsaturated bonds can be used independently, or two or more can be combined.

Specific examples of the compound (D) containing three or more ethylenically unsaturated bonds include compounds containing an allyl group such as triallyl isocyanurate (TAIC (registered trademark)), triallyl cyanurate, and the like, ditrimethylol propane tetra(meth)acrylate, compounds as expressed by the following general formulas (I) to (IV), and other (meth)acrylate compounds.

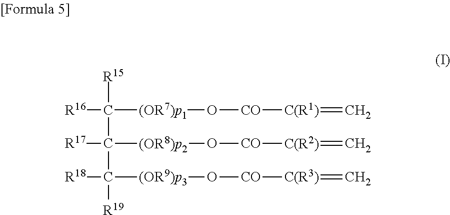

[Where R¹ to R³ individually represent a hydrogen atom or a methyl group; R⁷ to R⁹ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ individually represent an integer from 0 to 10; and R¹⁵ to R¹⁹ individually represent a hydrogen atom or an alkyl group with 1 to 10 carbon atoms.]

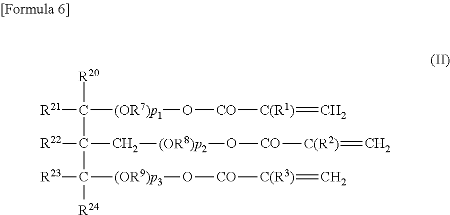

[Where R¹ to R³ individually represent a hydrogen atom or a methyl group; R⁷ to R⁹ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ individually represent an integer from 0 to 10; and R²⁰ to R²⁴ individually represent a hydrogen atom or an alkyl group with 1 to 10 carbon atoms.]

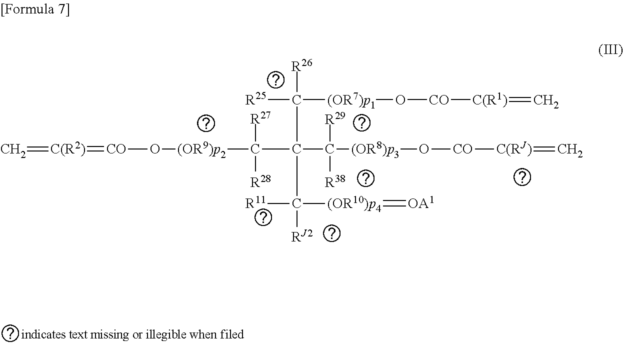

[Where R¹ to R³ individually represent a hydrogen atom or a methyl group; R⁷ to R¹⁰ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₄ individually represent an integer from 0 to 10; R²⁵ to R³² individually represent a hydrogen atom or an alkyl group with 1 to 10 carbon atoms; and A1 represents a hydrogen atom, an alkyl group, or —CO—C(R⁴)═CH₂ (where R⁴ represents a hydrogen atom or a methyl group).]

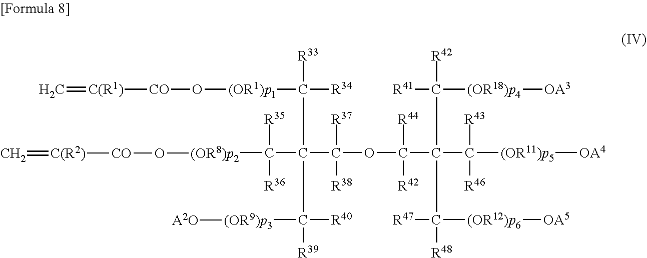

[Where R¹ to R³ individually represent a hydrogen atom or a methyl group; R⁷ to R¹² individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₆ individually represent an integer from 0 to 10; R³³ to R⁴⁸ individually represent a hydrogen atom or an alkyl group with 1 to 10 carbon atoms; one of A² and A³ represents —CO—C(R³)═CH₂ (where R represents a hydrogen atom or methyl group), and the other represents a hydrogen atom, an alkyl group, or —CO—C(R¹⁴)CH₂ (where R⁴ represents a hydrogen atom or methyl group), A⁴ represents a hydrogen group, an alkyl group, or —CO—C(R⁵)═CH₂ (where R represents a hydrogen atom or methyl group), and A⁵ represents a hydrogen atom, an alkyl group, or —CO—C(R⁶)═CH: (where R⁶ represents a hydrogen atom or methyl group).]

Herein, of these, a chain compound that does not have a cyclic structure in a molecule is preferably used as the compound (D) containing three or more ethylenically unsaturated bonds. This is because if a chain compound is used, the toughness of the curable resin molded article formed using the curable resin composition can be enhanced as compared to when using a cyclic compound having a cyclic structure in a molecule. Furthermore, this is because the cured product can have excellent heat resistance.

Furthermore, a compound that is liquid at ambient temperature and ambient pressure is preferably used as the compound (D) containing three or more ethylenically unsaturated bonds. This is because when the added amount of the aforementioned inorganic filler material (C) is increased in order to reduce the coefficient of linear expansion, the curable resin molded article obtained by molding the curable resin composition may become brittle (in other words, the toughness of the curable resin molded article may be reduced), but if a compound that is liquid at ambient temperature and ambient pressure is used as the compound (D) containing three or more ethylenically unsaturated bonds, the toughness of the curable resin molded article can be improved. Furthermore, this is because if a compound that is liquid at ambient temperature and ambient pressure is used, a curable resin molded article with ensured toughness can be formed even with a low amount of solvent used for preparing the curable resin composition, and therefore, void defects and the like can be suppressed from further occurring in the cured product.

Furthermore, a (meth)acrylate compound as expressed by the aforementioned general formulas (I) to (IV) is preferably used as the compound (D) containing three or more ethylenically unsaturated bonds from the perspective of being able to easily form a cured product having high heat resistance, where the occurrence of void defects and the like is suppressed. Of these, the compound (D) containing three or more ethylenically unsaturated bonds is more preferably pentaerythritol tri(meth)acrylate, pentaerythritol tetra(meth)acrylate, dipentaerythritol tri(meth)acrylate, dipentaerythritol tetra(meth)acrylate, dipentaerythritol penta(meth)acrylate, and dipentaerythritol hexa(meth)acrylate, and even more preferably dipentaerythritol hexa(meth)acrylate.

Furthermore, in the curable resin composition of the present invention, the ratio occupied by the compound (D) in a nonvolatile component of the curable resin composition is preferably 0.1 mass % or more, more preferably 0.3 mass % or more, even more preferably 0.5 mass % or more, and preferably 15 mass % or less, more preferably 10 mass % or less, and even more preferably 4 mass % or less. This is because if the ratio of the compound (D) in a nonvolatile component is 0.1 mass % or more, void defects and the like can be further suppressed in the cured product while sufficiently improving the heat resistance of the cured product. Furthermore, this is because if the ratio of the compound (D) in a nonvolatile component is 15 mass % or less, the dielectric tangent of the cured product can be suppressed from increasing.

Furthermore, in the curable resin composition of the present invention, the amount of the compound (D) containing three or more ethylenically unsaturated bonds is preferably 0.2 parts by mass or more, more preferably 0.5 parts by mass or more, and even more preferably 1.0 parts by mass or more, and preferably 30 parts by mass or less, more preferably 15 parts by mass or less, and even more preferably 7 parts by mass or less, per 100 parts by mass of the inorganic filler material (C). This is because if the amount of the compound (D) per 100 parts by mass of the inorganic filler material (C) is 0.5 parts by mass or more, void defects and the like can be further suppressed from occurring in the cured product while sufficiently improving the heat resistance of the cured product. Furthermore, this is because if the amount of the compound (D) per 100 parts by mass of the inorganic filler material (C) is 30 parts by mass or less, the dielectric tangent of the cured product can be suppressed from increasing.

### Solvent

Furthermore, a solvent such as an organic solvent or the like used when preparing the curable resin composition may be included in the curable resin composition of the present invention if necessary.

### Other Additives

Furthermore, the curable resin composition of the present invention may contain a curing accelerator at an optional amount if necessary. The curing accelerator is not particularly limited, and examples include aliphatic polyamines, aromatic polyamines, secondary amines, tertiary amines, acid anhydrides, imidazole derivatives, tetrazole derivatives, organic acid hydrazides, dicyandiamides and derivatives thereof, urea derivatives, and the like, but of these, imidazole derivatives are particularly preferable.

Furthermore, in order to improve flame retardancy in the curable resin composition of the present invention when used as a cured product, a flame retardant such as a halogen flame retardant, phosphorus flame retardant, and the like may be added for example. Furthermore, optional additives such as a flame retardant auxiliary agent, heat stabilizer, weathering stabilizer, age inhibitor, ultraviolet absorber (laser processability improving agent), leveling agent, antistatic agent, slipping agent, antiblocking agent, antifogging agent, lubricant, dye, natural oil, synthetic oil, wax, emulsion, magnetic material, dielectric property adjuster, toughness agent, or the like may be added at an arbitrary amount to the curable resin composition of the present invention if necessary.

### Method for Preparing the Curable Resin Composition

Furthermore, the aforementioned curable resin composition may be prepared by mixing the aforementioned components as is without particular limitation, may be prepared by mixing the components in a condition dissolved or dispersed in a solvent such as an organic solvent or the like, or may be prepared by preparing a composition in a condition where a portion of the components are dissolved or dispersed in a solvent and then the remaining components are mixed in the composition.

### Curable Resin Molded Article

The curable resin molded article of the present invention is obtained by molding the curable resin composition of the present invention into an arbitrary shape such as a sheet shape, film shape, or the like. Furthermore, the curable resin molded article of the present invention is not particularly limited, and examples include films formed by molding the curable resin composition of the present invention into a sheet shape or film shape, and prepregs formed by impregnating the curable resin composition of the present invention into a fiber substrate and forming into a sheet-shaped or film-shaped composite molded article.

Note that the curable resin molded article of the present invention is formed using the curable resin composition of the present invention, and therefore, a cured product having a low coefficient of linear expansion and high heat resistance, where the occurrence of void defects or the like is suppressed can be formed. Furthermore, the curable resin molded article of the present invention is formed using the curable resin composition of the present invention, and therefore, the molded article has favorable toughness.

### Film

Herein, a film used as the curable resin molded article of the present invention can be formed by coating the curable resin composition of the present invention with a solvent added as needed onto a supporting body, and then drying the curable resin composition on the supporting body if necessary. Furthermore, the film obtained as described above is used in a condition of remaining adhered onto the supporting body, or after peeling from the supporting body.

Note that examples of supporting bodies used in forming the film include a resin film, metal foil, or the like described in International Publication No. 2012/090980.

Furthermore, methods of coating the curable resin composition include tip coating, roll coating, curtain coating, die coating, slit coating, gravure coating, and the like.

Furthermore, the temperature when drying the curable resin composition coated on a supporting body is preferably a temperature to a degree where the curable resin composition of the present invention does not cure, which is normally 20° C. to 300° C., and preferably 30° C. to 200° C. When the drying temperature is too high, a curing reaction may excessively advance. Furthermore, the drying time is normally 30 seconds to 1 hour, and preferably 1 minute to 30 minutes.

Note that the thickness of the film is not particularly limited, but from the perspective of workability and the like, the thickness is normally 1 μm to 150 μm, preferably 2 μm to 100 μm, and more preferably 5 μm to 80 μm.

Furthermore, the film is preferably in a condition where the curable resin composition is uncured or semi-cured. Herein, uncured refers to a condition where the entire epoxy compound (A) is essentially dissolved when the film is immersed in a solvent that can dissolve the epoxy compound (A). Furthermore, semi-cured refers to a condition where curing is performed partway to an extent where further curing is possible if heated, and preferably a condition where a portion (specifically 7 mass % or more) of the epoxy compound (A) is dissolved when the film is immersed in a solvent that can dissolve the epoxy compound (A), or a condition where the volume after immersing the film for 24 hours in a solvent is 200% or more of the volume before immersing.

Note that the film formed using the curable resin composition of the present invention may be a multiple layer (multilayer) structure film of two or more layers. Specifically, the film is a film used in manufacturing a multilayer circuit board or the like, and may be a film with a two-layer structure formed from an adhesive layer where a first layer is adhered to a surface of a substrate, and formed from a layer to be plated where a second layer is formed on a conductor layer on the surface.

### Prepreg

Furthermore, a prepreg as the curable resin molded article of the present invention can be formed by impregnating the curable resin composition of the present invention with a solvent added as needed onto a fiber substrate, and then drying the curable resin composition if necessary.

Herein, examples of the fiber substrate used in forming the prepreg include polyamide fibers, polyaramide fibers, polyester fibers, and other organic fibers, glass fibers, carbon fibers, and other inorganic fibers. Furthermore, examples of the form of the fiber substrate include plain weave, twill weave, and other woven material forms, nonwoven material forms, and the like.

Furthermore, the method of impregnating the curable resin composition into the fiber substrate is not particularly limited, and examples include a method of immersing the fiber substrate in the curable resin composition with a solvent added in order to adjust the viscosity or the like, a method of coating the curable resin composition with a solvent added onto the fiber substrate, and the like. With a method of coating, the curable resin composition with a solvent added can be coated onto a fiber substrate placed on a supporting body.

Herein, drying of the curable resin composition impregnated in a fiber substrate can be performed similarly to the aforementioned film. Furthermore, the prepreg preferably includes the curable resin composition in an uncured or semi-cured condition, similar to the aforementioned film.

Note that the thickness of the prepreg is not particularly limited, but from the perspective of workability and the like, the thickness is normally 1 μm to 150 μm, preferably 2 μm to 100 μm, and more preferably 5 μm to 80 μm. Furthermore, the amount of the fiber substrates in the prepreg is normally 20 mass % to 90 mass %, and preferably 30 mass % to 85 mass %.

### Cured Product

A cured product of the present invention can be obtained by performing a curing treatment on the curable resin molded article of the present invention obtained by the aforementioned method. The curing treatment is normally a heat treatment on the curable resin molded article of the present invention.

Note that the cured product of the present invention is formed by curing the curable resin molded article of the present invention, and therefore has a low coefficient of linear expansion and high heat resistance, where the occurrence of void defects and the like is suppressed.

Herein, the curing temperature when curing the curable resin molded article is normally 30° C. to 400° C., preferably 70° C. to 300° C., and more preferably 100° C. to 250° C. Furthermore, the curing time is 0.1 hours to 5 hours, and preferably 0.5 hours to 3 hours. Furthermore, the method of heating is not particularly limited, and may be performed using an electric oven or the like for example.

### Laminate Body

A laminate body of the present invention is formed by laminating the aforementioned cured product of the present invention with a substrate. Furthermore, the laminate body of the present invention can be obtained by laminating the aforementioned curable resin molded article of the present invention onto a substrate, and then curing the curable resin molded article on the substrate for example.

Herein, a substrate having a conductor layer on a surface can be used as the substrate for example. The substrate having a conductor layer on the surface has a conductor layer on the surface of an electrical insulating substrate, for example. The electrical insulating substrate is formed by curing a resin composition containing a conventionally known electrical insulating material (such as an alicyclic olefin polymer, epoxy resin, maleimide resin, (meth)acrylic resin, diallyl phthalate resin, triazine resin, polyphenylene ether, glass, and the like). The conductor layer is not particularly limited, but normally may be a layer that includes wiring formed by a conductor such as a conductive metal or the like, and may include various circuits. The configuration, thickness, and the like of the wiring or circuit are not particularly limited. Specific examples of the substrate having a conductor layer on a surface can include printed circuit boards, silicon wafer substrates, and the like. Furthermore, the thickness of the substrate having a conductor layer on a surface is normally 10 μm to 10 mm, preferably 20 μm to 5 mm, and more preferably 30 μm to 2 mm.

Note that the substrate having a conductor layer on a surface may be pretreated by a known method from the perspective of improving adhesion with the cured product formed by curing the curable resin molded article of the present invention.

### Composite

A composite according to the present invention is provided with the laminate body of the present invention and a conductor layer formed on a surface of a cured product side of the laminate body. The composite can be obtained by further forming a conductor layer by a metal plating or metal foil on a surface of a layer (cured product) where the curable resin molded article is cured.

Furthermore, the composite can be used as a multilayer circuit board for example. Specifically, after curing the curable resin molded article according to the present invention on the conductor layer formed on a surface on the cured product side of the laminate body to produce an electrical insulating layer, an additional conductor layer can be formed in accordance with a method described in Japanese Unexamined Patent Application Publication No. 2012-136646 to obtain a desired multilayer circuit board for example.

A composite obtained thereby and a multilayer circuit board as one example of the composite of the present invention are formed provided with an electrical insulating layer (cured product of the present invention) formed by curing the curable resin molded article of the present invention, and the electrical insulating layer has a low coefficient of linear expansion and high heat resistance, where the occurrence of void defects and the like is suppressed, and therefore can be suitably used in various applications.

### Multilayer Printed Circuit Board

Furthermore, a multilayer printed circuit board of the present invention can be formed using the composite of the present invention.

### EXAMPLES

The present invention will be specifically described below based on examples, but the present invention is not limited to the examples thereof. Note that in the following description, “%” and “parts” expressing an amount are based on mass unless otherwise specified.

In the Examples and Comparative Examples, the nonvolatile component amount in the curable resin composition, film brittleness, cured product condition, heat resistance, and dielectric tangent were evaluated using the following methods.

### Nonvolatile Component Amount

Three grams of a prepared curable resin composition were placed on an aluminum dish, and then vacuum drying was performed for 3 hours at a temperature of 120° C. using a vacuum dryer. Furthermore, the mass of the curable resin composition remaining on the aluminum dish after vacuum drying was measured, and then the amount of nonvolatile component in the curable resin composition was calculated from the mass of the curable resin composition before and after vacuum drying.

### Film Brittleness

Five small pieces with a 20 mm width and 100 mm length were cut from a prepared film (curable resin molded article), and the cut out pieces were folded in two at 180 degrees with a center portion in the longitudinal direction as a boundary. Furthermore, the presence or absence of cracks (splits) was observed at the center portion of the small pieces after folding, and then evaluated based on the following criteria.

A: No cracks on any of the small pieces

B: Cracks on 1 or 2 small pieces

C: Cracks on 3 or more small pieces

### Cured Product Condition

A 10 mm square (10 mm length×10 mm width) range of a center portion of a prepared laminate body was observed with an optical microscope, and evaluated based on the following criteria. Note that void refers to a portion (gap) where cured resin was not present, and herein, indicates a portion with a maximum diameter of 5 μm or more.

A: A void was not observed.

B: 1 to fewer than 10 voids were observed.

C: 10 voids or more were observed.

### Heat Resistance

A dynamic viscoelasticity analysis (DMA method) was performed using a prepared film-shaped cured product, the glass transition temperature (Tg) of a resin (cured resin) configuring the cured product was determined from a peak temperature of a loss tangent, and then the heat resistance was evaluated based on the following criteria. Note that a DMS6100 standard type manufactured by SII Nanotechnology was used in the dynamic viscoelasticity analysis. As the glass transition temperature increases, excellent heat resistance will be exhibited.

A: Glass transition temperature was 170° C. or higher.

B: Glass transition temperature was 160° C. to less than 170° C.

C: Glass transition temperature was lower than 160° C.

### Dielectric Tangent

A small piece with a 2.0 mm width and 100 mm length was cut out from a prepared film-shaped cured product, measurements of the dielectric tangent at 5 GHz were performed using a dielectric constant measuring device of the cavity resonator perturbation method, and then evaluations were performed based on the following criteria.

A: Dielectric tangent was less than 0.0065.

B: Dielectric tangent was 0.0065 or more.

### Example 1

### Preparation of Curable Resin Composition

One-hundred parts of an epoxy compound having a dicyclopentadiene skeleton (product name: “Epiclon HP-7200H” manufactured by DIC corporation, epoxy group equivalent weight: 278) as the epoxy compound (A), 80 parts of an active ester curing agent (product name: “HPC8000-65T”, a toluene solution having a 65 mass % nonvolatile content, manufactured by DIC Corporation, active ester equivalent weight: 223) as the epoxy curing agent (B), calculated as solid content, 350 parts of silica (product name: “SC2500-SXJ” manufactured by Admatechs, volume average particle size: 0.5 μm, surface treated with a secondary aminosilane coupling agent) as the inorganic filler material (C), 4 parts of the dipentaerythritol hexaacrylate (hexafunctional chain compound that is liquid at ambient temperature and ambient pressure) as the compound (D) containing three or more ethylenically unsaturated bonds, 0.2 parts of Irganox 3114 (manufactured by BASF) as an age inhibitor, 0.2 parts of Curezol 2PZ (manufactured by Shikoku Chemicals Corporation) as a curing accelerator, and 100 parts of methylethyl ketone as an organic solvent were mixed and stirred for 5 minutes with a planetary stirrer to obtain a varnish of a curable resin composition.

### Preparation of Film

Next, the varnish of a curable resin composition obtained as described above was coated onto a 300 mm×30 mm polyethylene terephthalate film (supporting body, thickness: 38 μm) provided with a release layer on a surface, and then dried for 5 minutes at 80° C. under a nitrogen atmosphere to form a 43 μm thick film (curable resin molded article) on the supporting body. Furthermore, the brittleness of the obtained film was evaluated in accordance with the aforementioned method. The results are shown in Table 1.

### Preparation of Laminate Body

Next, separately from the aforementioned film, a 160 mm square (160 length×160 mm width) double-sided copper-clad substrate on which copper with a thickness of 0.8 μm was adhered was prepared on a surface of a core substrate obtained by impregnating varnish containing a glass filler and a halogen-free epoxy compound into glass fibers. Furthermore, a laminate body with a wiring width and a distance between wires of 50 μm and a thickness of 18 μm, and which had been micro-etching treated by bringing a surface into contact with an organic acid, was formed onto a surface of the double-sided copper-clad substrate to obtain an inner layer substrate.

The film with a supporting body (curable resin molded article) obtained as described above was cut into a 150 mm square and then adhered to both surfaces of the inner layer substrate such that a surface on the curable resin molded article side was on the inside, and then primary pressing was performed. Primary pressing was performed for 30 seconds at a pressure of 0.7 MPa and a pressure bonding temperature of 120° C. under reduced pressure conditions of 0.8 hPa using a vacuum laminator provided with heat resistant rubber pressing plates at the top and bottom. Next, secondary pressing was performed on the obtained primary pressing processed product using a hydraulic pressing device provided with metal pressing plates at the top and bottom. Secondary pressing was performed for 60 seconds at a pressure of 0.9 MPa and a pressure bonding temperature of 100° C. under atmospheric pressure. Thereafter, the obtained secondary pressing processed product was allowed to stand at room temperature for 30 minutes, and then heated for 30 minutes at 180° C., and the curable resin molded article was cured to obtain a cured resin layer (cured product). Finally, the supporting body was peeled from the cured resin layer to obtain a laminate body formed from the cured resin layer (cured product) and inner layer substrate. The condition of the cured product was evaluated in accordance with the aforementioned method, using the obtained laminate body. The results are shown in Table 1.

### Preparation of Film-Shaped Cured Product

A small piece cut out from the film with a supporting body obtained above was laminated onto a 10 μm thick copper foil such that the film was on the inside (copper foil side) in a condition with the supporting body attached. Furthermore, the uncured laminate body of the copper foil and film with a supporting body was thermal pressure bonded for 60 seconds at a pressure of 0.1 MPa, temperature of 110° C., and reduced pressure of 0.8 hPa, using a vacuum laminator provided with heat resistant rubber pressing plates at the top and bottom. Next, after allowing to stand for 30 minutes at room temperature, heating was performed for 30 minutes at a temperature of 180° C. in air. Furthermore, the supporting body was peeled away, and heating and curing were performed for 90 minutes at a temperature of 190° C., and then the cured resin with a copper foil was cut out and the copper foil was dissolved in a 1 mol/L ammonium persulfate aqueous solution to obtain a film-shaped cured product. The heat resistance and dielectric tangent of the cured product were evaluated in accordance with the aforementioned method, using the obtained film-shaped cured product. The results are shown in Table 1.

### Example 2

A curable resin composition, film, laminate body, and film-shaped cured product were manufactured similarly to Example 1 with the exception that a mixture of 85 parts of a biphenol epoxy compound (product name: “NC3000L” manufactured by Nippon Kayaku Co., Ltd., epoxy group equivalent weight: 269) and 15 parts of a polyfunctional epoxy compound (product name: “1031S” manufactured by Mitsubishi Chemical Corporation, epoxy group equivalent weight: 200) was used as the epoxy compound (A), the added amount of the active ester curing agent as the epoxy curing agent (B) was changed to 65 parts, the added amount of the silica as the inorganic filler material (C) was changed to 330 parts, and the added amount of dipentaerythritol hexaacrylate (hexafunctional chain compound that is liquid at ambient temperature and ambient pressure) as the compound (D) containing three or more ethylenically unsaturated bonds was changed to 10 parts when preparing the curable resin composition. Furthermore, various evaluations were performed similarly to Example 1. The results are shown in Table 1.

### Example 3

A curable resin composition, film, laminate body, and film-shaped cured product were manufactured similarly to Example 1 with the exception that 100 parts of a biphenol epoxy compound (product name: “NC3000L” manufactured by Nippon Kayaku Co., Ltd., epoxy group equivalent weight: 269) was used as the epoxy compound (A), the added amount of the active ester curing agent as the epoxy curing agent (B) was changed to 83 parts, and 2.5 parts of triallyl isocyanurate (TAIC: trifunctional, cyclic compound that is solid at ambient temperature and ambient pressure) was used as the compound (D) containing three or more ethylenically unsaturated bonds when preparing the curable resin composition. Furthermore, various evaluations were performed similarly to Example 1. The results are shown in Table 1.

### Example 4

A curable resin composition, film, laminate body, and film-shaped cured product were manufactured similarly to Example 1 with the exception that 100 parts of a biphenol epoxy compound (product name: “NC3000L” manufactured by Nippon Kayaku Co., Ltd., epoxy group equivalent weight: 269) was used as the epoxy compound (A), the added amount of the active ester curing agent as the epoxy curing agent (B) was changed to 83 parts, the added amount of the silica as the inorganic filler material (C) was changed to 400 parts, and the added amount of the dipentaerythritol hexaacrylate (hexafunctional chain compound that is liquid at ambient temperature and ambient pressure) as the compound (D) containing three or more ethylenically unsaturated bonds was changed to 31 parts when preparing the curable resin composition. Furthermore, various evaluations were performed similarly to Example 1. The results are shown in Table 1.

### Example 5

A curable resin composition, film, laminate body, and film-shaped cured product were manufactured similarly to Example 1 with the exception that 100 parts of a biphenol epoxy compound (product name: “NC3000L” manufactured by Nippon Kayaku Co., Ltd., epoxy group equivalent weight: 269) was used as the epoxy compound (A), the added amount of the active ester curing agent as the epoxy curing agent (B) was changed to 83 parts, and 4.5 parts of ditrimethylolpropane tetraacrylate (tetrafunctional, chain compound that is liquid at ambient temperature and ambient pressure) was used as the compound (D) containing three or more ethylenically unsaturated bonds when preparing the curable resin composition. Furthermore, various evaluations were performed similarly to Example 1. The results are shown in Table 1.

### Comparative Example 1

A curable resin composition, film, laminate body, and film-shaped cured product were manufactured similarly to Example 1 with the exception that the added amount of the active ester curing agent as the epoxy curing agent (B) was changed to 80 parts, the added amount of the silica as the inorganic filler material (C) was changed to 342 parts, and the compound (D) containing three or more ethylenically unsaturated bonds was not added when preparing the curable resin composition. Furthermore, various evaluations were performed similarly to Example 1. The results are shown in Table 1.

### Comparative Example 2

A curable resin composition, film, laminate body, and film-shaped cured product were manufactured similarly to Example 1 with the exception that 100 parts of a biphenol epoxy compound (product name: “NC3000L” manufactured by Nippon Kayaku Co., Ltd., epoxy group equivalent weight: 269) was used as the epoxy compound (A), the added amount of the active ester curing agent as the epoxy curing agent (B) was changed to 83 parts, the added amount of the silica as the inorganic filler material (C) was changed to 37 parts, and 17 parts of a polyethylene glycol diacrylate containing 2 ethylenically unsaturated bonds (bifunctional chain compound that is liquid as ambient temperature and ambient pressure) was used in place of the compound (D) containing three or more ethylenically unsaturated bonds when preparing the curable resin composition. Furthermore, various evaluations were performed similarly to Example 1. The results are shown in Table 1.

TABLE 1

| | | | | Exam- | Exam- | Exam- | Exam- |
|---|---|---|---|---|---|---|---|
| | | | | ple 1 | ple 2 | ple 3 | ple 4 |
| Curable | Epoxy Compound (A) | | HP7200H | 100 | — | — | — |
| Resin | | | [parts by mass] | | | | |
| Composition | | | NC3000L | — | 85 | 100 | 100 |
| | | | [parts by mass] | | | | |
| | | | 1031S | — | 15 | — | — |
| | | | [parts by mass] | | | | |
| | Epoxy Curing Agent (B) | | HPC8000-65T | 80 | 65 | 83 | 83 |
| | | | [parts by mass] | | | | |
| | Inorganic Filler Material (C) | | SC2500-SXJ | 350 | 330 | 350 | 400 |
| | | | [parts by mass] | | | | |
| | Compound Containing | Hexafunctional | Dipentaerythritol | 4 | 10 | — | 31 |
| | Ethylenically | | Hexaacrylate | | | | |
| | Unsaturated | | [parts by mass] | | | | |
| | Bond | Trifunctional | Triallyl Isocyanurate | — | — | 2.5 | — |
| | | | [parts by mass] | | | | |
| | | Tetrafunctional | Ditrimethylolpropane | — | — | — | — |
| | | | Tetraacrylate | | | | |
| | | | [parts by mass] | | | | |
| | | Bifunctional | Polyethylene Glycol | — | — | — | — |
| | | | Diacrylate | | | | |
| | | | [parts by mass] | | | | |

| | | | | | |
|---|---|---|---|---|---|
| Age Inhibitor | Irganox 3114 | 0.2 | 0.2 | 0.2 | 0.2 |
| | [parts by mass] | | | | |
| Curing accelerator | Curezol 2PZ | 0.2 | 0.2 | 0.2 | 0.2 |
| | [parts by mass] | | | | |

| | | | | | |
|---|---|---|---|---|---|
| | Inorganic Filler Material (C)/Nonvolatile Component [mass %] | 65 | 65 | 65 | 65 |
| | Compound Containing Ethylenically Unsaturated Bond/Nonvolatile Component [mass %] | 0.7 | 2 | 0.5 | 5 |
| | Compound Containing Ethylenically Unsaturated Bond/100 Parts of Inorganic | 1.1 | 3.0 | 0.7 | 7.8 |
| | Filler Material (C) [parts by mass] | | | | |
| Evaluation | Film Brittleness | A | A | B | A |
| | Cured Product Condition | A | A | A | A |
| | Heat Resistance | A | A | A | A |
| | Dielectric Tangent | A | A | A | B |

| | | | Exam- | Comparative | Comparative |
|---|---|---|---|---|---|
| | | | ple 5 | Example 1 | Example 2 |
| Curable | Epoxy Compound (A) | HP7200H | — | 100 | — |
| Resin | | [parts by mass] | | | |
| Composition | | NC3000L | 100 | — | 100 |
| | | [parts by mass] | | | |
| | | 1031S | — | — | — |
| | | [parts by mass] | | | |
| | Epoxy Curing Agent (B) | HPC8000-65T | 83 | 80 | 83 |
| | | [parts by mass] | | | |
| | Inorganic Filler Material (C) | SC2500-SXJ | 350 | 342 | 370 |
| | | [parts by mass] | | | |

| | | | | | |
|---|---|---|---|---|---|
| Compound Containing | Hexafunctional | Dipentaerythritol | — | — | — |
| Ethylenically | | Hexaacrylate | | | |
| Unsaturated | | [parts by mass] | | | |
| Bond | Trifunctional | Triallyl Isocyanurate | — | — | — |
| | | [parts by mass] | | | |
| | Tetrafunctional | Ditrimethylolpropane | 4.5 | — | — |
| | | Tetraacrylate | | | |
| | | [parts by mass] | | | |
| | Bifunctional | Polyethylene Glycol | — | — | 17 |
| | | Diacrylate | | | |
| | | [parts by mass] | | | |

| | | | | |
|---|---|---|---|---|
| Age Inhibitor | Irganox 3114 | 0.2 | 0.2 | 0.2 |
| | [parts by mass] | | | |
| Curing accelerator | Curezol 2PZ | 0.2 | 0.2 | 0.2 |
| | [parts by mass] | | | |

| | | | | |
|---|---|---|---|---|
| | Inorganic Filler Material (C)/Nonvolatile Component [mass %] | 65 | 65 | 65 |
| | Compound Containing Ethylenically Unsaturated Bond/Nonvolatile Component [mass %] | 0.8 | — | 3 |
| | Compound Containing Ethylenically Unsaturated Bond/100 Parts of Inorganic | 1.3 | — | 4.6 |
| | Filler Material (C) [parts by mass] | | | |
| Evaluation | Film Brittleness | A | C | A |
| | Cured Product Condition | A | B | A |
| | Heat Resistance | A | B | C |
| | Dielectric Tangent | A | A | A |

From Table 1, the cured products of Examples 1 to 5 are seen to have heat resistance and suppressed occurrences of void defects or the like. Furthermore, the films of Examples 1 to 5 are seen to be capable of ensuring sufficient toughness. On the other hand, the cured product of Comparative Example 1 exhibited low heat resistance, and was unable to suppress the occurrence of void defects or the like. Furthermore, the film of Comparative Example 1 was found to be incapable of ensuring toughness. Furthermore, the cured product of Comparative Example 2 is seen to have low heat resistance. Note that the inorganic filler material was sufficiently added for all cured products, and therefore, the coefficient of linear expansion was sufficiently low.

### INDUSTRIAL APPLICABILITY

The present invention can provide a curable resin composition having a low linear expansion coefficient and high heat resistance, which can form a cured product where the occurrence of void defects and the like is suppressed, and can ensure toughness of a molded article.

Furthermore, the present invention can provide a curable resin molded article having favorable toughness and having a low coefficient of linear expansion and high heat resistance, which can form a cured product where the occurrence of void defects and the like is suppressed.

Furthermore, the present invention can provide a cured product having a low coefficient of linear expansion and high heat resistance, where the occurrence of void defects and the like is suppressed, as well as a laminate body, composite, and multilayer printed circuit board formed using the cured product.

1. A curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %.

2. The curable resin composition according to claim 1, wherein the compound containing three or more ethylenically unsaturated bonds is a chain compound.

3. The curable resin composition according to claim 1, wherein the compound containing three or more ethylenical unsaturated bonds includes a compound that is liquid at ambient temperature and ambient pressure.

4. The curable resin composition according to claim 1, wherein the compound containing three or more ethylenically unsaturated bonds includes at least one type of compound selected from a group comprising (meth)acrylate compounds as expressed by the following general formulas: 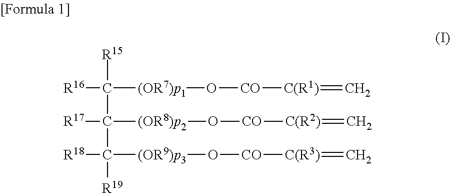
[where R¹ to R³ individually represent a hydrogen atom or a methyl group; R⁷ to R⁸ individually represent —CH(R¹³)—CH(R¹⁴)— (where R¹³ and R¹⁴ individually represent a hydrogen atom or an alkyl group with 1 to 5 carbon atoms) or —(CH)₄—; p₁ to p₃ individually represent an Integer from 0 to 10; and R¹⁵ to R¹⁹ individually represent a hydrogen atom or an alkyl group with 1 to 10 carbon atoms.]; 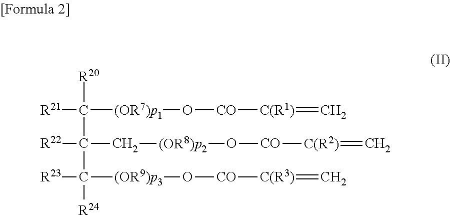
[where R¹ to R³ individually represent a hydrogen atom or a methyl group; R⁷ to R⁹ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₃ Individually represent an integer from 0 to 10; and R²⁰ to R²⁴ individually represent a hydrogen atom or an alkyl group with 1 to 10 carbon atoms.]; 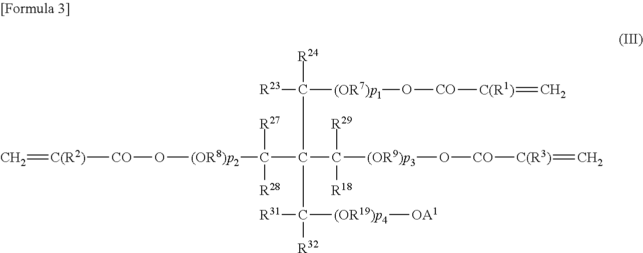
[where R¹ to R³ individually represent a hydrogen atom or a methyl group; R⁷ to R¹⁰ individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₄ individually represent an integer from 0 to 10; R²⁵ to R³² individually represent a hydrogen atom or an alkyl group with 1 to 10 carbon atoms; and A¹ represents a hydrogen atom, an alkyl group, or —CO—C(R⁴)═CH₂ (where R⁴ represents a hydrogen atom or a methyl group).]; and 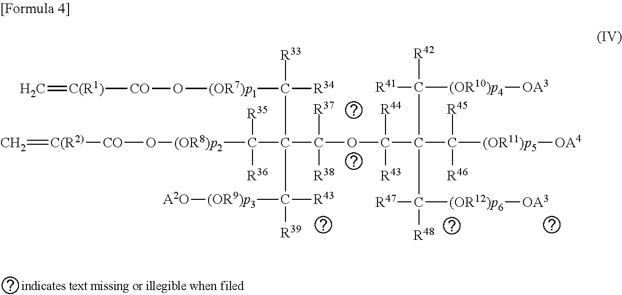
[where R¹ to R³ individually represent a hydrogen atom or a methyl group; R⁷ to R¹² individually represent —CH(R¹³)—CH(R¹⁴)— (where R¹³ and R¹⁴ individually represent a hydrogen atom or an alkyl group with 1 to 5 carbon atoms) or —(CH₂)₄—; p₁ to p₆ individually represent an integer from 0 to 10; R³³ to R⁴⁸ individually represent a hydrogen atom or an alkyl group with 1 to 10 carbon atoms; one of A² and A³ represents CO—C(R³)═CH₂ (where R³ represents a hydrogen atom or methyl group), and the other represents a hydrogen atom, an alkyl group, or —CO—C(R⁴)═CH₂ (where R⁴ represents a hydrogen atom or a methyl group); A⁴ represents a hydrogen atom, an alkyl group, or —CO—C(R⁵)═CH₂ (where R⁵ represents a hydrogen atom or a methyl group); and A⁵ represents a hydrogen atom, an alkyl group, or —CO—C(R⁶)═CH₂ (where R⁶ represents a hydrogen atom or a methyl group).].

5. The curable resin composition according to claim 1, wherein the ratio of the compound containing three or more ethylenically unsaturated bonds in a nonvolatile component is 0.1 mass % to 15 mass %.

6. The curable resin composition according to claim 1, comprising the compound containing three or more ethylenically unsaturated bonds at a ratio of at least 0.2 parts by mass to not more than 30 parts by mass per 100 parts by mass of the inorganic filler material.

7. The curable resin composition according to claim 1, wherein the epoxy curing agent contains an active ester curing agent.

8. A curable resin molded article formed using a curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %.

9. A cured product formed by curing a curable resin molded article formed using a curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %.

10. A laminate body formed by laminating a substrate and a cured product formed by curing a curable resin molded article formed using a curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %.

11. A composite, comprising:
a laminate body formed by laminating a substrate and a cured product formed by curing a curable resin molded article formed using a curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %; and
a conductor layer formed on a surface of the laminate body on the cured product side.

12. A multilayer printed circuit board formed using a composite, comprising:
a laminate body formed by laminating a substrate and a cured product formed by curing a curable resin molded article formed using a curable resin composition, comprising:
an epoxy compound;
an epoxy curing agent;
an inorganic filler material; and
a compound containing three or more ethylenically unsaturated bonds; wherein
the ratio of the inorganic filler material in a nonvolatile component exceeds 50 mass %; and
a conductor layer formed on a surface of the laminate body on the cured product side.
